(19) United States
(12) Patent Application Publication
(10) Pub. No.: US 2023/0178515 A1
(43) Pub. Date: Jun. 8, 2023

(54) DOUBLE-SIDED PACKAGE STRUCTURE AND MANUFACTURING METHOD THEREOF

(71) Applicant: LUXSHARE ELECTRONIC TECHNOLOGY (KUNSHAN) LTD., Kunshan City (CN)

(72) Inventors: Xiaolei ZHOU, Kunshan City (CN); Yong ZHOU, Kunshan City (CN); Wenbin KANG, Kunshan City (CN)

(73) Assignee: LUXSHARE ELECTRONIC TECHNOLOGY (KUNSHAN) LTD., Kunshan City (CN)

(21) Appl. No.: 17/825,814

(22) Filed: May 26, 2022

(30) Foreign Application Priority Data
Dec. 6, 2021 (CN) 202111476407.8

(51) Int. Cl. H01L 25/065; H01L 23/498; H01L 21/48; H01L 21/56; H01L 25/00

(52) U.S. Cl. CPC H01L 25/0652; H01L 23/49833; H01L 21/4853; H01L 21/565; H01L 21/568; H01L 25/50; H01L 2225/0651; H01L 2225/06517; H01L 2225/06558; H01L 2225/06572; H01L 2225/06582

(57) ABSTRACT

A manufacturing method of a double-sided package structure includes securing at least two discrete double-sided mount structures to a first side of a master at intervals; molding the first side of the master to form a molded body encasing the at least two discrete double-sided mount structures; removing the master; and splitting the molded body to obtain individual double-sided package structures.

### CROSS-REFERENCE TO RELATED APPLICATION(S)

This application claims priority to Chinese Patent Application No. 202111476407.8 filed on Dec. 6, 2021, the disclosure of which is incorporated herein by reference in its entirety.

### TECHNICAL FIELD

The present disclosure relates to the chip packaging technologies, and in particular to a double-sided package structure and a manufacturing method thereof.

### BACKGROUND

With the continuous development of semiconductor technologies, to satisfy more and more application requirements, electronic packages are becoming smaller and smaller. To reduce the area of a product, components need to be mounted onto two faces of a substrate, thereby improving the utilization rate. However, mounting components onto the two faces of the substrate brings difficulties for double-sided packaging. The double-sided packaging requires a complex technique and more technical processes than traditional single-sided packaging. As a result, the production costs and the production cycle are greatly increased.

### SUMMARY

Embodiments of the present disclosure provide a double-sided package structure and a manufacturing method thereof so that components on two surfaces of a double-sided mount structure can be molded simultaneously in one molding process, thereby simplifying the technical process, reducing the difficulty of the packaging technique, and ameliorating the warpage problem of the substrate of the double-sided package structure.

In a first aspect, embodiments of the present disclosure provide a manufacturing method of a double-sided package structure. The method includes the steps below.

At least two discrete double-sided mount structures are secured to a first side of a master at intervals.

The first side of the master is molded such that a molded body encasing the at least two discrete double-sided mount structures is formed.

The master is removed.

The molded body is split such that individual double-sided package structures are obtained.

Optionally, that the at least two discrete double-sided mount structures are secured to the first side of the master at intervals includes the step below.

Electrical connection structures in the at least two discrete double-sided mount structures are soldered onto a pad of the master.

Optionally, after the master is removed, the method further includes the step below.

The molded body on one side of the master is thinned and removed such that the electrical connection structures are exposed.

Optionally, after the molded body on one side of the master is thinned and removed such that the electrical connection structures are exposed, the method further includes the steps below.

A solder ball is embedded in the exposed electrical connection structures.

The solder ball is reflowed such that the solder ball and the electrical connection structure are fused into an external solder ball.

Optionally, that the at least two discrete double-sided mount structures are secured to the first side of the master at intervals includes the step below.

The electrical connection structures in the at least two discrete double-sided mount structures are partially sunk into a temporary adhesive layer of the master.

Optionally, the temporary adhesive layer includes at least one of a pyrolysis adhesive tape, a photolysis adhesive tape or a chemical etching adhesive tape.

Optionally, that the master is removed includes the step below.

The temporary adhesive layer is removed such that the master is separated from the molded body.

Optionally, one electrical connection structure includes any one of the following structures: a first solder ball, a communication carrier board and a second solder ball that are stacked together; a third solder ball; or a copper column.

Optionally, before the at least two discrete double-sided mount structures are secured to the first side of the master at intervals, the method further includes the steps below.

Components are mounted onto a first face of the substrate.

Components are mounted onto a second face of the substrate, where the first face is opposite to the second face.

The substrate whose two faces are mounted with the components is split such that individual double-sided mount structures are formed.

Optionally, that the molded body is split such that individual double-sided package structures are obtained includes the step below.

The molded body is split by being cut such that the individual double-sided package structures are obtained, where a cutting line has a width greater than a width of a gap between adjacent double-sided mount structures.

In a second aspect, embodiments of the present disclosure provide a double-sided package structure manufactured by the manufacturing method described in the first aspect.

The double-sided package structure includes a double-sided mount structure and a molded body encasing the double-sided mount structure. The double-sided mount structure includes a substrate and components mounted onto two opposite surfaces of the substrate.

In the manufacturing method of a double-sided package structure provided by the embodiment of the present disclosure, the at least two discrete double-sided mount structures are secured to the first side of the master, the at least two discrete double-sided mount structures are molded such that the molded body is formed, the master is removed, and the molded body is split such that the individual double-sided package structures are obtained. Components on two surfaces of a double-sided mount structure are molded simultaneously in one molding process, thereby simplifying the technical process and reducing the difficulty of the packaging technique. Moreover, multiple individual double-sided mount structures are molded, and the multiple double-sided mount structures do not share the same substrate; therefore the difference between the upper moldflow pressure of the substrate and the lower moldflow pressure of the substrate is reduced when the double-sided molding is performed, thereby alleviating the warpage problem of the substrate of the double-sided package structure formed by being packaged.

### BRIEF DESCRIPTION OF DRAWINGS

FIG. 1 is a flowchart of a manufacturing method of a double-sided package structure according to embodiments of the present disclosure.

FIGS. 2 to 7 are views illustrating a manufacturing process of a double-sided package structure according to embodiments of the present disclosure.

FIG. 8 is a flowchart of a manufacturing method of a double-sided mount structure in the manufacturing method of a double-sided package structure.

FIGS. 9 to 11 are views illustrating a manufacturing process of a double-sided mount structure according to embodiments of the present disclosure.

FIG. 12 is a flowchart of a manufacturing method of another double-sided package structure according to embodiments of the present disclosure.

FIG. 13 is a flowchart of a manufacturing method of another double-sided package structure according to embodiments of the present disclosure.

FIGS. 14 to 17 are views illustrating a manufacturing process of another double-sided package structure according to embodiments of the present disclosure.

### DETAILED DESCRIPTION

The present disclosure is further described hereinafter in detail in conjunction with drawings and embodiments. It is to be understood that the embodiments described herein are merely intended to explain the present disclosure and not to limit the present disclosure. Additionally, it is to be noted that for ease of description, only part, not all, of the structures related to the present disclosure are illustrated in the drawings.

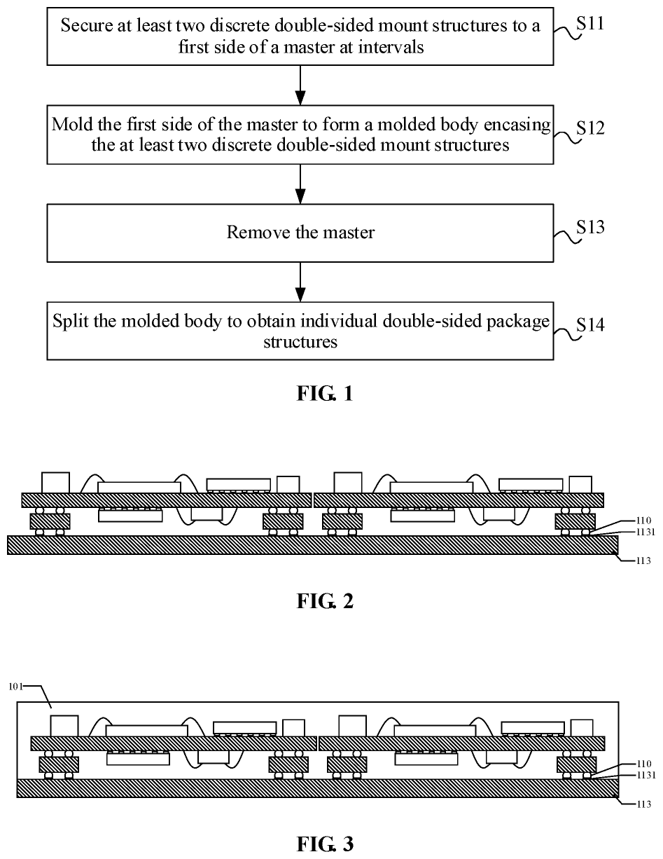

FIG. 1 is a flowchart of a manufacturing method of a double-sided package structure according to embodiments of the present disclosure, and FIGS. 2 to 7 are views illustrating a manufacturing process of a double-sided package structure according to embodiments of the present disclosure. The manufacturing method of a double-sided package structure is used for forming a double-sided package structure. Referring to FIGS. 1 to 7, the manufacturing method of a double-sided package structure includes the steps below.

In S11, at least two discrete double-sided mount structures are secured to a first side of a master 113 at intervals.

In a double-sided mount structure, two opposite surfaces of the substrate are each mounted with components, and the components may include, for example, a chip. Referring to FIG. 2, two double-sided mount structures are taken as an example for illustration. The two discrete double-sided mount structures are secured to the first side of the master 113 at intervals. The two double-sided mount structures use two individual substrates. That is, the two double-sided mount structures do not share the same substrate. A certain gap may exist between the two double-sided mount structures.

In S12, the first side of the master 113 is molded such that a molded body 101 encasing the at least two discrete double-sided mount structures is formed.

Referring to FIG. 3, the two double-sided mount structures secured to the master 113 are packaged in the molded body 101 by being molded. The components on two surfaces of a double-sided mount structure are molded in the same molding process.

In S13, the master 113 is removed.

In S14, the molded body 101 is split such that individual double-sided package structures are obtained.

In the manufacturing method of a double-sided package structure provided in this embodiment of the present disclosure, the at least two discrete double-sided mount structures are secured to the first side of the master 113, the at least two discrete double-sided mount structures are molded such that the molded body 101 is formed, the master 113 is removed, and the molded body 101 is split such that individual double-sided package structures are obtained.

The components on the two surfaces of the double-sided mount structure are molded simultaneously in one molding process, thereby simplifying the technical process and reducing the difficulty of the packaging technique. Moreover, multiple individual double-sided mount structures are molded, and the multiple double-sided mount structures do not share the same substrate; therefore the difference between the upper moldflow pressure of the substrate and the lower moldflow pressure of the substrate is reduced when the double-sided molding is performed, thereby alleviating the warpage problem of the substrate of the double-sided package structure formed by being packaged.

As an example, embodiments of the present disclosure further provide a manufacturing method of a double-sided mount structure. The manufacturing method of a double-sided mount structure can be used for manufacturing a double-sided mount structure that serves as an object to be packaged on a master to form a double-sided package structure. That is, the manufacturing process of a double-sided mount structure is the front part in the manufacturing process of a double-sided package structure.

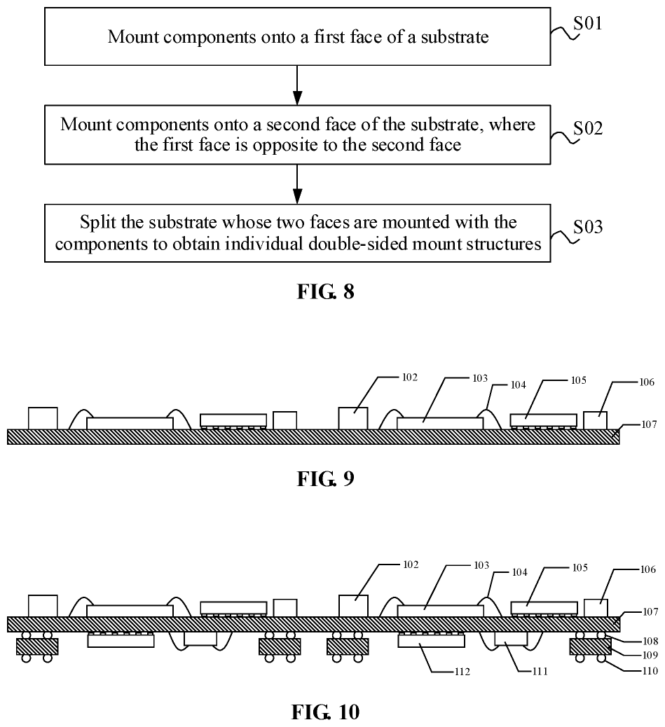

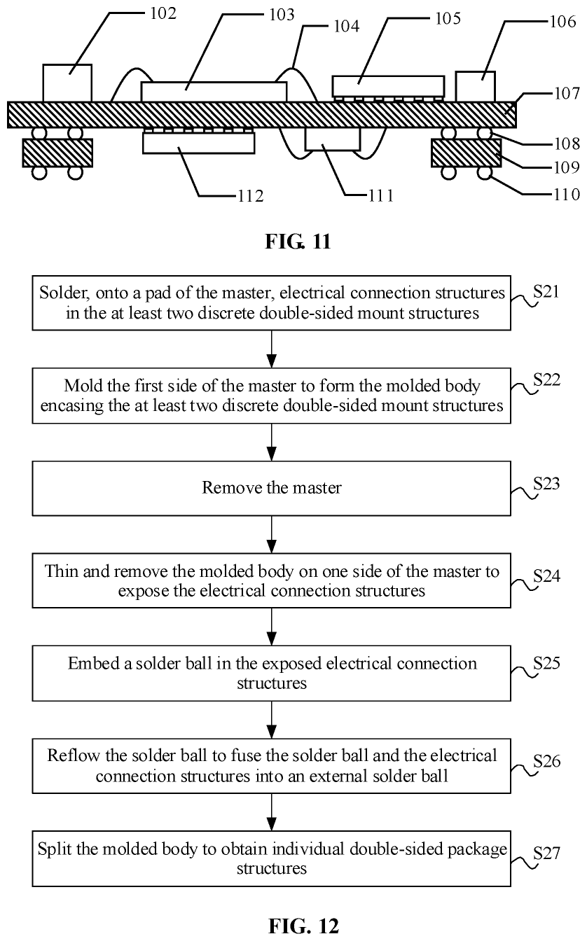

FIG. 8 is a flowchart of a manufacturing method of a double-sided mount structure in the manufacturing method of a double-sided package structure, and FIGS. 9 to 11 are views illustrating a manufacturing process of forming a double-sided mount structure according to embodiments of the present disclosure. Referring to FIGS. 8 to 11, the method further includes the steps below.

In S01, components are mounted onto a first face of a substrate 107.

Referring to FIG. 9, components are mounted onto the first face of the substrate 107. Multiple kinds of mounting technologies may be used here for mounting different types of components. For example, the surface-mount technology is used for mounting components 102 and 106, the wire bonding technology is used for mounting a component 103 (a bondwire 104 may be an alloyed wire, a copper wire, a gold wire or an aluminum wire), and the flip chip technology is used for mounting a component 105. The preceding is only for illustration. In practice, a single mounting technology may be used, or a combination of several mounting technologies may be used.

In S02, components are mounted onto a second face of the substrate 107, where the first face is opposite to the second face.

Referring to FIG. 10, components are mounted onto the second face of the substrate 107. Multiple kinds of mounting technologies may also be used here for mounting different components. For example, the surface-mount technology is used for mounting the electrical connection structures (in this embodiment, an example is illustrated in which one electrical connection structure includes a first solder ball 108, a communication carrier board 109 and a second solder ball 110 that are stacked together), the wire bonding technology is used for mounting a component 111, and the flip chip technology is used for mounting a component 112. The preceding is only for illustration. In practice, a single mounting technology may be used, or a combination of several mounting technologies may be used. One electrical connection structure formed by the first solder 108, the communication carrier board 109 and the second solder ball 110 enables the substrate 107 to communicate with and be soldered onto the outside.

In S03, the substrate 107 whose two faces are mounted with the components is split such that individual double-sided mount structures are formed.

In the manufacturing method of a double-sided mount structure provided in this embodiment, the first face of the substrate 107 is mounted with the components, the second face of the substrate 107 is mounted with the components, and the substrate 107 whose two faces are mounted with the components is split such that individual double-sided mount structures are formed.

FIG. 12 is a flowchart of a manufacturing method of another double-sided package structure according to embodiments of the present disclosure. Referring to FIGS. 2 to 12, in this embodiment, a description is given by using an example in which one electrical connection structure includes the first solder ball 108, the communication carrier board 109 and the second solder ball 110 that are stacked together. The method includes the steps below.

In S21, electrical connection structures in the at least two discrete double-sided mount structures are soldered onto a pad 1131 of the master 113.

Referring to FIG. 2, in the at least two discrete double-sided mount structures, the second solder ball 110 is soldered onto the pad 1131 of the master 113 so that the at least two discrete double-sided mount structures are secured to the master 113, thereby preventing the at least two discrete double-sided mount structures from being impacted and moved by a molding fluid in the subsequent molding process.

In S22, the first side of the master 113 is molded such that a molded body 101 encasing the at least two discrete double-sided mount structures is formed.

Referring to FIGS. 3 to 7, the two double-sided mount structures secured to the master 113 are packaged in the molded body 101 by being molded. The molded body 101 molds and packages the components 102, 103, 105 and 106 on the first face of the substrate 107; and the components 111 and 112 on the second face of the substrate 107, the first solder ball 108 on the second face of the substrate 107, the communication carrier board 109 on the second face of the substrate 107, and the second solder ball 110 on the second face of the substrate 107.

In S23, the master 113 is removed.

In S24, the molded body 101 on one side of the master 113 is thinned and removed such that the electrical connection structures are exposed.

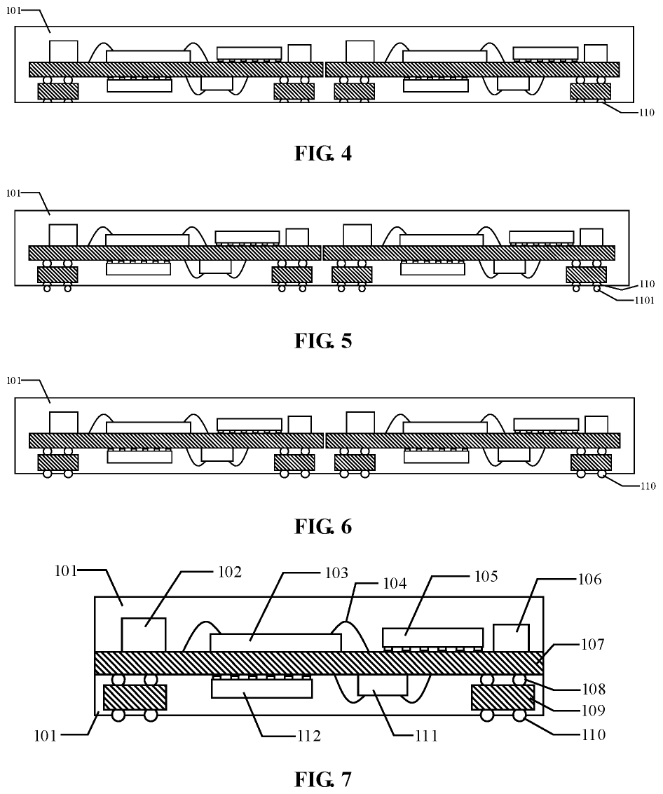

For example, referring to FIG. 4, the thinning technique may use the grinding technique, that is, the molded body 101 on one side of the master 113 is removed by being ground until the second solder ball 110 is exposed. It is to be understood that other thinning techniques may be also used for thinning the molded body 101, for example, the dry etching technique or the wet etching technique.

For example, referring to FIG. 4, when the molded body 101 on one side of the master 112 is removed by being ground, the thickness of the second solder ball 110 may be partially removed by being ground, and the grinding may be stopped near the center line of the second solder ball 110. The exposed area of the second solder ball 110 is the largest near the center line of the second solder ball 110, laying a foundation for subsequent embedment of solder balls and subsequent soldering.

In S25, a solder ball is embedded in the exposed electrical connection structures.

Referring to FIG. 5, a solder ball is embedded in the second solder ball 110 (the embedded solder ball is denoted as a solder ball 1101).

In S26, the solder ball is reflowed such that the solder ball and the electrical connection structures are fused into an external solder ball.

Referring to FIGS. 5 and 6, after being melted, the solder ball 1101 and the remaining second solder ball 110 are fused to form a new complete solder ball that serves as the external solder ball (the newly formed solder ball is located at the position of the second solder ball 110 before the grinding, so the newly formed solder ball is denoted as the solder ball 110).

In S27, the molded body 101 is split such that individual double-sided package structures are obtained.

In the manufacturing method of a double-sided package structure provided in this embodiment, the molded body 101 on one side of the master 113 is thinned and removed such that the electrical connection structures are exposed, the solder ball 1101 is embedded in the exposed electrical connection structures, and the embedded solder ball 1101 is reflowed. In this manner, the electrical connection structures encased by the molded body 101 are led out of the molded body 101 via the external solder ball (that is the solder ball 110) formed by fusion, thereby facilitating the double-sided package structure to be electrically connected to other substrates or the assembly board via the electrical connection structures.

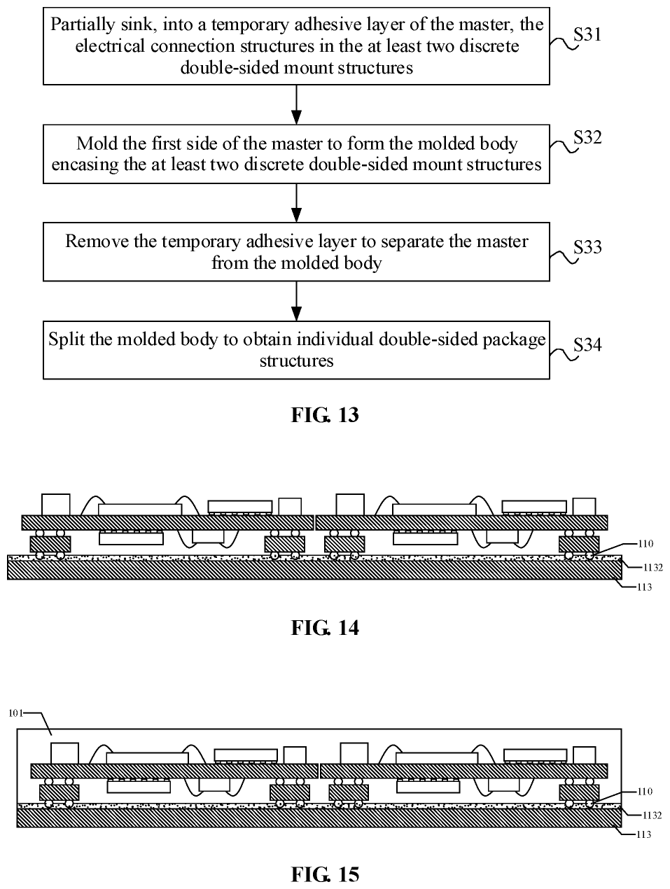

FIG. 13 is a flowchart of a manufacturing method of another double-sided package structure according to embodiments of the present disclosure, and FIGS. 14 to 17 are views illustrating a manufacturing process of another double-sided package structure according to embodiments of the present disclosure. In this embodiment, a description is given by using an example in which one electrical connection structure includes the first solder ball 108, the communication carrier board 109 and the second solder ball 110 that are stacked together. In conjunction with FIGS. 9 to 11 and FIGS. 13 to 17, the method includes the steps below.

In S31, the electrical connection structures in the at least two discrete double-sided mount structures are partially sunk into a temporary adhesive layer 1132 of the master 113.

Referring to FIG. 14, in the at least two discrete double-sided mount structures, the second solder ball 110 is partially sunk into the temporary adhesive layer 1132 of the master 113 so that the at least two discrete double-sided mount structures are secured to the master 113, thereby preventing the at least two discrete double-sided mount structures from being impacted and moved by a molding fluid in the subsequent molding process.

Optionally, the temporary adhesive layer 1132 includes at least one of a pyrolysis adhesive tape, a photolysis adhesive tape or a chemical etching adhesive tape.

For example, the depth of the second solder ball 110 sunk into the temporary adhesive layer 1132 is greater than the radius of the second solder ball 110, and thus the part of the second solder ball 110 protected by the temporary adhesive layer 1132 is large enough. At least half of the second solder ball 110 is exposed after the temporary adhesive layer 1132 and the master 113 are removed, laying a foundation for being soldered onto other substrates or the assembly board.

In S32, the first side of the master 113 is molded such that the molded body 101 encasing the at least two discrete double-sided mount structures is formed.

Referring to FIG. 15, the second solder ball 110 is partially sunk into the temporary adhesive layer 1132 of the master 113, so when the at least two discrete double-sided mount structures are molded, the second solder ball 110 sunk into the temporary adhesive layer 1132 is protected by the temporary adhesive layer 1132, thereby preventing from being encased by the molded body 101.

In S33, the temporary adhesive layer 1132 is removed such that the master 113 is separated from the molded body.

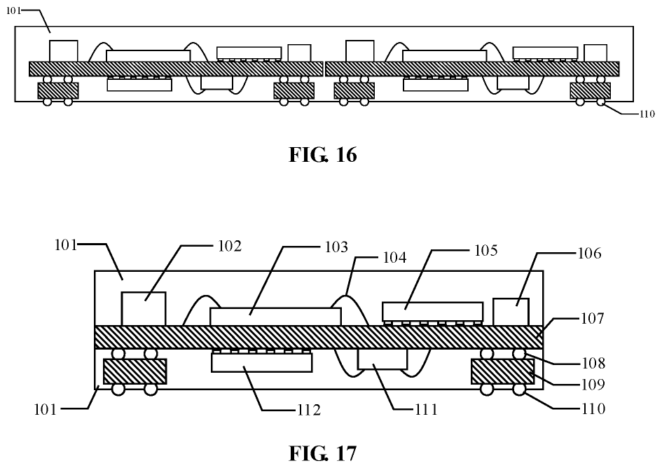

Referring to FIG. 16, if the temporary adhesive layer 1132 includes the pyrolysis adhesive tape, the temporary adhesive layer 1132 may be removed by pyrolysis by being heated; if the temporary adhesive layer 1132 includes the photolysis adhesive tape, the temporary adhesive layer 1132 may be removed by pyrolysis by being illuminated; and if the temporary adhesive layer 1132 includes the chemical etching tape, the temporary adhesive layer 1132 may be removed by pyrolysis by being chemically etched. After the temporary adhesive layer 1132 is removed, since the adhesive force of the temporary adhesive layer 1132 does not exist, the master 107 is separated from the molded body 101.

In S34, the molded body 101 is split such that individual double-sided package structures are obtained.

In the manufacturing method of a double-sided package structure provided in the embodiment, the electrical connection structures in the at least two discrete double-sided mount structures are partially sunk into the temporary adhesive layer 1132 of the master 113, the at least two discrete double-sided mount structures are molded such that the molded body 101 is formed, the temporary adhesive layer 1132 is removed such that the master is separated from the molded body. In this manner, the electrical connection structures without being encased by the molded body 101 directly are exposed out of the molded body 101, thereby facilitating the double-sided package structure to be electrically connected to other substrates and the assembly board via the electrical connection structures.

In the preceding embodiment, the example is illustrated in which one electrical connection structure includes the first solder ball 108, the communication carrier board 109 and the second solder ball 110 that are stacked together. With the communication carrier board 109 as the adapter board, the second solder ball 110 may be rearranged on the communication carrier board 109 relative to the position of the first solder ball 108, thereby flexibly satisfying the requirements of various situations on the number of pins and the distribution state of the pins. Moreover, high environment-polluting techniques do not exist.

In an embodiment, one electrical connection structure may include a third solder ball. That is, a large solder ball is used for replacing the first solder ball 108, the communication carrier board 109 and the second solder ball 110.

In another embodiment, one electrical connection structure may include a copper column. That is, the copper column is used for replacing the first solder ball 108, the communication carrier board 109 and the second solder ball 110.

Optionally, referring to FIGS. 16 and 17, that the molded body 101 is split such that the individual double-sided package structures are obtained includes splitting the molded body 101 by cutting the molded body 101 such that the individual double-sided package structures are obtained, where a cutting line has a width greater than a width of a gap between adjacent double-sided mount structures. Therefore, when the molded body 101 is split along the cutting lines by being cut, a part of the substrate 107 adjacent to the gap between the adjacent double-sided mount structures is removed, thereby facilitating exposing the ground wire of the side end face of the substrate 107. It is to be understood that in a case where the ground wire of the side end face of the substrate 107 does not need to be exposed, the cutting line does not need to be configured to have the width greater than the width of the gap between the adjacent double-sided mount structures; when the molded body 101 is split along the cutting lines by being cut, the molded body 101 is split, and the substrate 107 is not split; and in the formed individual double-sided package structures after the cutting, the side face of the substrate 107 may be encased by the molded body 101.

Embodiments of the present disclosure further provide a double-sided package structure manufactured by the manufacturing method described in the preceding embodiments. Referring to FIGS. 7, the double-sided package structure includes a double-sided mount structure and a molded body 101 encasing the double-sided mount structure. The double-sided mount structure includes a substrate 107 and components mounted onto two opposite surfaces of the substrate 107.

For example, the components 102, 103, 105 and 106 are mounted onto a first side of the substrate 107, the components 111 and 112, the first solder ball 108, the communication carrier board 109 and the second solder ball 110 are mounted onto a second side of the substrate 107, and the first side of the substrate 107 is opposite to the second side of the substrate 107.

It is to be noted that the preceding are only preferred embodiments of the present disclosure and technical principles used therein. It is to be understood by those skilled in the art that the present disclosure is not limited to the embodiments described herein. Those skilled in the art can make various apparent modifications, adaptations, combinations and substitutions without departing from the scope of the present disclosure. Therefore, while the present disclosure has been described in detail through the preceding embodiments, the present disclosure is not limited to the preceding embodiments and may include more other equivalent embodiments without departing from the concept of the present disclosure. The scope of the present disclosure is determined by the scope of the appended claims.

What is claimed is:

1. A manufacturing method of a double-sided package structure, comprising:
securing at least two discrete double-sided mount structures to a first side of a master at intervals;
molding the first side of the master to form a molded body encasing the at least two discrete double-sided mount structures;
removing the master; and
splitting the molded body to obtain individual double-sided package structures.

2. The manufacturing method according to claim 1, wherein securing the at least two discrete double-sided mount structures to the first side of the master at intervals comprises:
soldering, onto pads of the master, electrical connection structures in the at least two discrete double-sided mount structures.

3. The manufacturing method according to claim 2, after removing the master, the method further comprising:
thinning and removing the molded body on one side of the master to expose the electrical connection structures.

4. The manufacturing method according to claim 3, after thinning and removing the molded body on the one side of the master to expose the electrical connection structures, the method further comprising:
embedding a solder ball in the exposed electrical connection structures; and
reflowing the solder ball to fuse the solder ball and the electrical connection structures into an external solder ball.

5. The manufacturing method according to claim 1, wherein securing the at least two discrete double-sided mount structures to the first side of the master at intervals comprises:
partially sinking, into a temporary adhesive layer of the master, electrical connection structures in the at least two discrete double-sided mount structures.

6. The manufacturing method according to claim 5, wherein the temporary adhesive layer comprises at least one of a pyrolysis adhesive tape, a photolysis adhesive tape or a chemical etching adhesive tape.

7. The manufacturing method according to claim 5, wherein removing the master comprises:
removing the temporary adhesive layer to separate the master from the molded body.

8. The manufacturing method according to claim 1, before securing the at least two discrete double-sided mount structures to the first side of the master at intervals, further comprising:
mounting components onto a first face of a substrate;
mounting components onto a second face of the substrate, wherein the first face is opposite to the second face; and
splitting the substrate whose two faces are mounted with the components to form individual double-sided mount structures.

9. The manufacturing method according to claim 1, wherein splitting the molded body to obtain the individual double-sided package structures comprises:
splitting the molded body by cutting the molded body to obtain the individual double-sided package structures,
wherein a cutting line has a width greater than a width of a gap between adjacent ones of the at least two double-sided mount structures.

10. A double-sided package structure manufactured by a manufacturing method, wherein the manufacturing method of the double-sided package structure comprises:
securing at least two discrete double-sided mount structures to a first side of a master at intervals;
molding the first side of the master to form a molded body encasing the at least two discrete double-sided mount structures;
removing the master; and
splitting the molded body to obtain individual double-sided package structures;
wherein the double-sided package structure comprises a double-sided mount structure and a molded body encasing the double-sided mount structure, wherein
the double-sided mount structure comprises a substrate and components mounted onto two opposite surfaces of the substrate.

11. The double-sided package structure manufactured by the manufacturing method according to claim 10, wherein securing the at least two discrete double-sided mount structures to the first side of the master at intervals comprises:
soldering, onto pads of the master, electrical connection structures in the at least two discrete double-sided mount structures.

12. The double-sided package structure manufactured by the manufacturing method according to claim 11, after removing the master, the method further comprising:
thinning and removing the molded body on one side of the master to expose the electrical connection structures.

13. The double-sided package structure manufactured by the manufacturing method according to claim 12, after thinning and removing the molded body on the one side of the master to expose the electrical connection structures, the method further comprising:
embedding a solder ball in the exposed electrical connection structures; and
reflowing the solder ball to fuse the solder ball and the electrical connection structures into an external solder ball.

14. The double-sided package structure manufactured by the manufacturing method according to claim 10, wherein securing the at least two discrete double-sided mount structures to the first side of the master at intervals comprises:
partially sinking, into a temporary adhesive layer of the master, electrical connection structures in the at least two discrete double-sided mount structures.

15. The double-sided package structure manufactured by the manufacturing method according to claim 14, wherein the temporary adhesive layer comprises at least one of a pyrolysis adhesive tape, a photolysis adhesive tape or a chemical etching adhesive tape.

16. The double-sided package structure manufactured by the manufacturing method according to claim 14, wherein removing the master comprises:
removing the temporary adhesive layer to separate the master from the molded body.

17. The double-sided package structure manufactured by the manufacturing method according to claim 10, before securing the at least two discrete double-sided mount structures to the first side of the master at intervals, further comprising:
mounting components onto a first face of a substrate;
mounting components onto a second face of the substrate, wherein the first face is opposite to the second face; and
splitting the substrate whose two faces are mounted with the components to form individual double-sided mount structures.

18. The double-sided package structure manufactured by the manufacturing method according to claim 10, wherein splitting the molded body to obtain the individual double-sided package structures comprises:
splitting the molded body by cutting the molded body to obtain the individual double-sided package structures,
wherein a cutting line has a width greater than a width of a gap between adjacent ones of the at least two double-sided mount structures.
